(19) United States
(12) Patent Application Publication
(10) Pub. No.: US 2016/0006436 A1
(43) Pub. Date: Jan. 7, 2016

(54) AUTOMATION KEYPAD WITH TRANSPARENT BUTTONS

(71) Applicant: Crestron Electronics, Inc., Rockleigh, NJ (US)

(72) Inventors: George Feldstein, Cresskill, NJ (US); Stanley Wisniewski, Pompton Plains, NJ (US); Philip Bellingham, White Plains, NY (US)

(21) Appl. No.: 14/323,118

(22) Filed: Jul. 3, 2014

(51) Int. Cl. H03K 17/96

(52) U.S. Cl. CPC H03K 17/9622; H03K 2217/94089; H03K 2217/960785; H03K 2217/96062; H03K 2217/960745; H03K 2217/960755

(57) ABSTRACT

A unitary transparent/translucent button element with UV ink curable graphics directly printed thereon having a sensing circuit that detects touch gestures made on or in front of the transparent element directly through an illuminating Light Emitting Diode (LED) lighting layer. Engraved markings help a user to identify the corresponding key function.

### BACKGROUND OF THE INVENTION

1. Technical Field

This disclosure relates to control system input controllers and more particularly, to improved wall mounted remote control keypads for controlling home or building automation.

2. Background Art

The popularity of home and building automation has increased in recent years in partly due to increases in affordability, improvements in simplicity, and a higher level of technical sophistication of the average end-user.

Generally, automation systems integrate various electrical and mechanical system elements within a building, such as a residential home or commercial building. Examples of system elements commonly found in both residential and commercial settings may include: Heating, Ventilation and Air Conditioning (HVAC), lighting control systems, audio and video (A/V) switching and distribution, motorized window treatments (including: blinds, shades, drapes, curtains, etc.), domestic robotics, swimming pool systems, occupancy and/or lighting sensors, and/or motorized or hydraulic actuators, and security systems, to name a few.

One way a user can be given control of an automation system, is through the use of one or more remote control devices, such as a keypad. Keypads typically have one or more buttons or keys that are assigned to performing a predetermined or assigned function. Assigned functions may include, for example, orchestrating of various lighting presets. Lighting presets are sometimes called “scenes.” Keypads can be mounted on to a building's walls. Keypads can also be mounted into a recessed receptacle in a wall, commonly known as a wall box. The various components of a keypad may be assembled into the keypad's housing body, which in turn, can be installed into a wall box.

### BRIEF SUMMARY OF THE INVENTION

It is to be understood that both the general and detailed descriptions that follow are only exemplary and are not restrictive.

The present disclosure is described in the context of a residential (or commercial) automation lighting system, however, it should be noted that the present invention is equally capable of deployment in other applications including, but not limited to: Heating, Ventilation and Air Conditioning (HVAC) systems, lighting control systems, audio and video (A/V) switching and distribution, motorized window treatments (including: blinds, shades, drapes, curtains, etc.), domestic robotics, swimming pool systems, occupancy and/or lighting sensors, and/or motorized or hydraulic actuators, and security systems, for example.

In one aspect, the present invention provides a method for manufacturing a one-piece transparent element with graphics directly printed thereon. The transparent element is preferably transparent or translucent so that it appears as if it were a glass-like material.

In another aspect, a Light Emitting Diode (LED) lighting layer illuminates the transparent element creating a unique and distinctive glass-like glowing appearance. The appearance can be modified or enhanced by using a diffusing medium having one or more light emitting diodes uniformly illuminating the translucent light diffusing medium.

In another aspect, a sensing circuit is provided to detect gestures made on the front of the transparent element through the lighting layer.

In yet another aspect, the transparent element may further include engraved markings help a user to identify the corresponding key function.

In another aspect, the transparent element keypad can provide visual or haptic vibration feedback to a user according to, a gesture, automation condition, function, or the like.

In another aspect, the keypad communicates with other devices using infrared technology. Communications may include programming or feedback control information.

In yet another aspect, the keypad can capture visual data using a camera or optical image sensor. The visual data may include a hand gesture made by a user for controlling the keypad, a printed barcode, a printed Quick Response (QR) code, information on ambient lighting levels, an image of a user's face, or fingerprint.

In yet another aspect, a passive infrared sensor (PIR) can be included for detecting motion in the proximity of the keypad assembly.

The present invention will now be described, in a non-limiting manner, referring to illustrations, where like reference numerals designate corresponding parts throughout the several views. The drawings are not necessarily drawn to scale, emphasis instead being placed upon clearly illustrating the principles of the present invention.

### BRIEF DESCRIPTION OF THE SEVERAL VIEWS OF THE DRAWINGS

Other advantages of the present invention will be readily appreciated, as the same becomes better understood by reference to the following detailed description when considered in connection with the accompanying drawings wherein:

FIG. 1 is an exploded front perspective view of an exemplary keypad.

FIG. 2 is a perspective view of a transparent element having flat engraved buttons.

FIG. 3 is a perspective view of the keypad of FIG. 1 assembled, with a transparent element having one side molded with vertically adjacent semi-cylindrical buttons.

FIG. 4 is a front elevation perspective view of a keypad installed within a wall box faceplate.

FIG. 5 is a side perspective view of a transparent element having one side molded with vertically adjacent semi-cylindrical buttons.

FIG. 6 is a rear perspective view of a transparent element having one side molded with vertically adjacent semi-cylindrical buttons, and the other with ink directly printed thereon.

FIG. 7 shows the steps of an illustrative method of manufacturing an automation keypad with its transparent element printed directly thereon.

FIG. 8 shows the steps of an illustrative method of using any of the keypads shown in FIG. 1, 3, or 4.

The following is a list of the major elements in the drawings.
1 Transparent element
2 Housing
3 Lighting layer
4 ink layer
5 Second printed layer
6 Light switch face Plate
7 Bezel
8 Iconic Symbols
9 Retaining plate
10 First split button
11 Second split button
12 Hand-held remote body
13 Sensing circuit
14 Haptic module
16 Image sensor
17 LED Array
18 Camera
19 IR transmitter/receiver
700 Start method of manufacturing
702 Step of providing a one-piece transparent element
704 Step of reverse printing
708 Step of curing
710 Step assembling
712 Step of engraving
714 End method of manufacturing
800 Start method of using keypad
802 Step of providing a one-piece transparent element
804 Step of performing a gesture
806 Step of detecting
808 Step of illuminating the light pipe
810 Step of varying illumination intensity
812 End method of using keypad

### DETAILED DESCRIPTION OF THE INVENTION

In the following description, numerous specific details are set forth to provide thorough explanation of embodiments of the present invention. It will be apparent, however, to one skilled in the art, that embodiments of the present invention may be practiced without these specific details. In other instances, well-known components, structures, and techniques have not been shown in detail in order not to obscure the understanding of this description.

Reference in the specification to “one embodiment” or “an embodiment” means that a particular feature, structure, or characteristic described in connection with the embodiment can be included in at least one embodiment of the invention. The appearances of the phrase “in one embodiment” in various places in the specification do not necessarily all refer to the same embodiment.

It is to be noted that the following exemplary embodiments are only illustrative. Alterations of the described embodiments are possible. Embodiments of the invention will next be described with reference to the figures, wherein like numerals indicate corresponding parts throughout the several views.

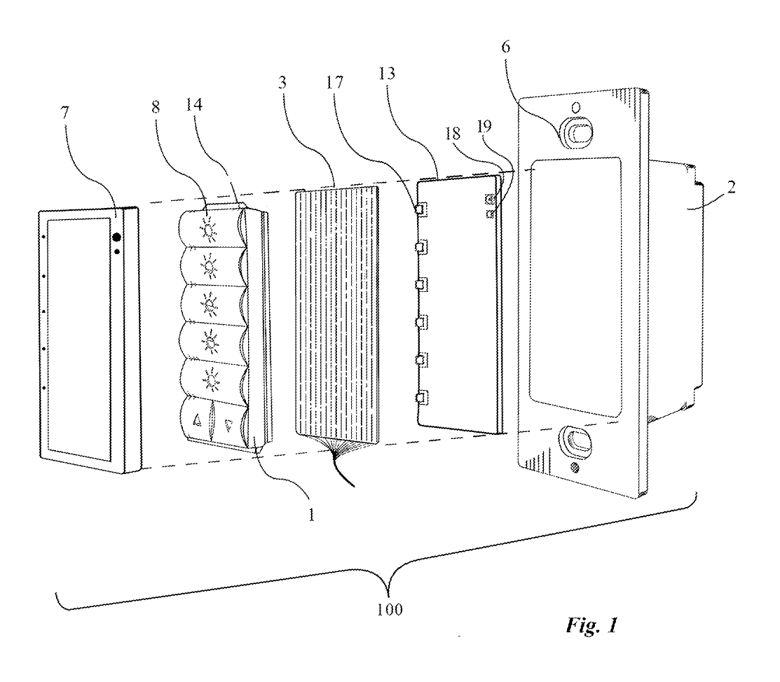

Referring now to FIG. 1, shown is a keypad device 100 that includes a substantially transparent element 1. In the preferred embodiment, transparent element 1 is transparent enough to allow the user to see a printed ink layer 4 directly printed on the backside of transparent element 1. Accordingly, transparent element 1 can be manufactured from any substantially clear material. Substantially clear materials may include: glass, acrylic, polymer, vinyl, polyester, polyethylene, polycarbonate, styrene plastic, or the like.

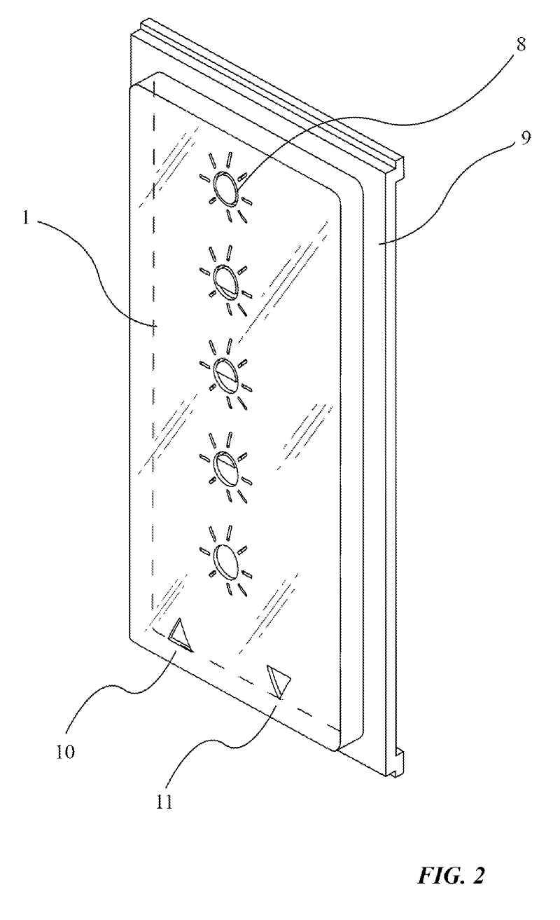

The keypad 100 can provide vibration feedback to a user, for example, by embedding a motorized haptic module 14 within transparent element 1. Vibration feedback can be made in response to touch or sliding gestures a user makes upon the transparent element 1. The transparent element 1 can be molded to present a touch surface. The touch surface can be molded as a plurality of vertically adjacent semi-cylindrical buttons or to present a flat surface (as shown in FIG. 2). Various areas of the transparent element 1 may be assigned to various functions, including contextually based functions. In one embodiment, these assigned areas on the touch surface can be engraved with one or more iconic symbols 8 corresponding to an automation function. The engraved iconic symbols 8 help users identify the corresponding key function. The iconic symbol 8 engraving may be in the form of etching, engraving, or may be the embedding of additional material such as metal, colored plastic, etc. In an embodiment, the transparent element 1 may include a first split button 10 and second split button 11.

Backlighting is provided by lighting layer 3 located directly behind transparent element 1. Lighting layer 3 illuminates the transparent element 1 creating a unique and distinctive glass-like glowing appearance. In one embodiment, the illumination of transparent element 1 is accomplished using a fiber optic grid (or mesh) piping light along a flat planar diffusing surface. Other kinds of lighting layers 3 translucent light diffusing mediums can be used. For example, one having several light emitting diodes dispersed uniformly along a translucent light diffusing medium. Additionally, the illumination intensity from the lighting layer 3 may also be varied illumination in order to provide visual feedback according to a gesture, or an automation condition.

Still referring to FIG. 1, a sensing circuit 13 detects gestures made on the transparent element 1. The transparent element 1 is placed inside of a bezel that is secured to the keypad housing 2. The housing 2 is suitable for installation into a standard wall box (not shown). In one embodiment, the keypad's sensing circuit 13 detects touch using capacitance sensing technology. Capacitance sensing technology is able to detect sliding gestures, inter alia, using mutual-capacitance, self-capacitance, etc. In one embodiment, sensing circuit 13 may be implemented for detecting capacitive input on the transparent element 1. The capacitive surface responds to a change in capacitance caused by change in the dielectric. In other words, the Sensing circuit 13 responds to the presence of a finger (or other object); even without physical contact on the Sensing circuit 13. However, it should be noted that the sensing technology of keypad 100 is not limited to a capacitive sensing surface. Other exemplary embodiments may include thermal sensing, and/or resistive sensing switching elements, detection using infra-red light, or an optical camera.

Sensing circuit 13 is positioned so that the lighting layer 3 is sandwiched in between the transparent element 1 and the sensing circuit 13. In other words, sensing circuit 13 detects touch through the lighting layer 3.

Sensing circuit 13 may include a LED Array 17 as indicator lights to indicate a user's selections. For example, an indicator light next to the iconic symbols 8 may indicate that a shade is open or closed, or a light is on or off, etc. In another embodiment, light pipe indications may be provided. The indicator lights may be viewable through a plurality of pinholes on bezel 7.

In an embodiment, the keypad 100 can communicate with other devices using infrared technology using an IR transmitter/receiver 19. Communications may include programming or feedback control information.

In another embodiment, the keypad 100 can capture visual data using a camera or optical image sensor 18. Visual data may include a hand gesture made by a user for controlling the keypad. The hand gestures may be made in front or a distance away from the keypad. The optical image sensor 18 can be configured to capture a printed barcode or a Quick Response (QR) code. Codes may be used as a way to authenticate user or to convey programming information to the keypad. The optical image sensor 18 may also be used to capture the ambient lighting level near the keypad. Other uses for the optical image sensor include 18 capturing biometric information such as, a user's face, or a user's fingerprint. A passive infrared sensor (PIR) can be included for detecting motion in the proximity of the keypad 100 assembly.

In an exemplary embodiment, the keypad 100 is connected to a building automation system. The connection may be wire or wireless.

In operation, the user can designate one or more automation functions by touching the transparent element 1 in a designated area. The designated area can be correspondingly marked by a named function or graphic icon 8. The sensing circuit 13 is configured to detect a user's selection and cause the automation system to respond by, for example, executing a corresponding function.

Sensing circuit 13 is responsible for detecting input from a user, for example, the user touching or pressing on a specific portion of the exposed surface of transparent element 1. Sensing circuit 13 may be implemented as a plurality of switching elements which are configured to detect a user's input, for example, by the capacitance resulting from a finger on or near any iconic Symbols 8, which are engraved on transparent element 1. Iconic Symbols 8 signify to a user, the various functions that can be selected, e.g., by touching the respective portion of transparent element 1. For example, different areas of the transparent element 1 may correspond to different functions, as illustrated in FIG. 1 by the iconic symbols 8.

Referring now to FIG. 2, shown is an embodiment where the touch surface of transparent element 1 is molded to present a flat surface. The touch surface has iconic symbols 8 representing engraved buttons.

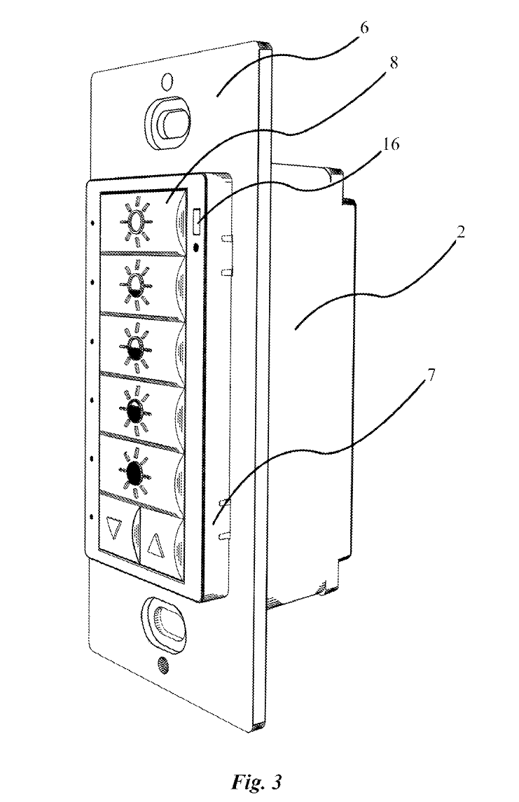

FIG. 3 shows the assembled keypad of FIG. 1. The transparent element 1 is placed inside of a bezel 7 and secured over the lighting layer 3 and sensing circuit 13 to faceplate 6 of keypad housing 2. In the preferred embodiment, the housing 2 is suitable for installation into a standard wall box.

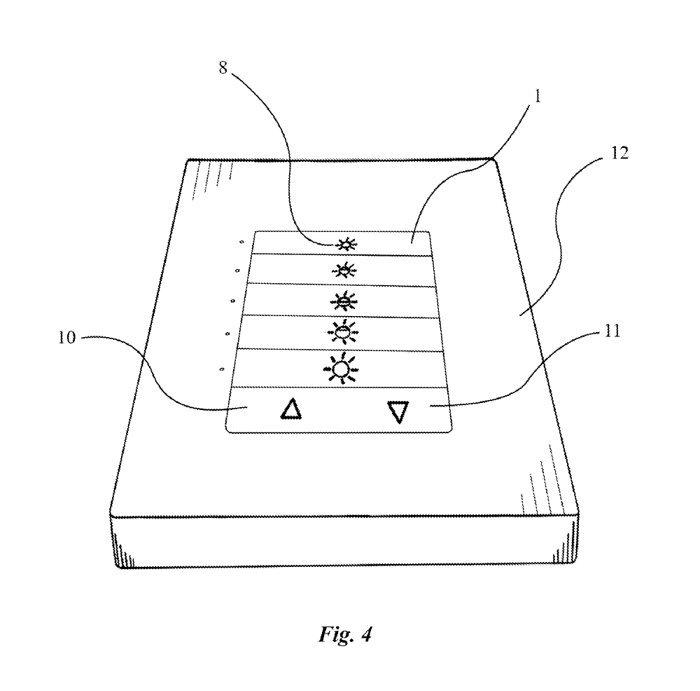

Now turning to FIG. 4, a portable remote hand-held keypad may include a hand-held remote body 12. In this embodiment, remote body 12 functions as the housing.

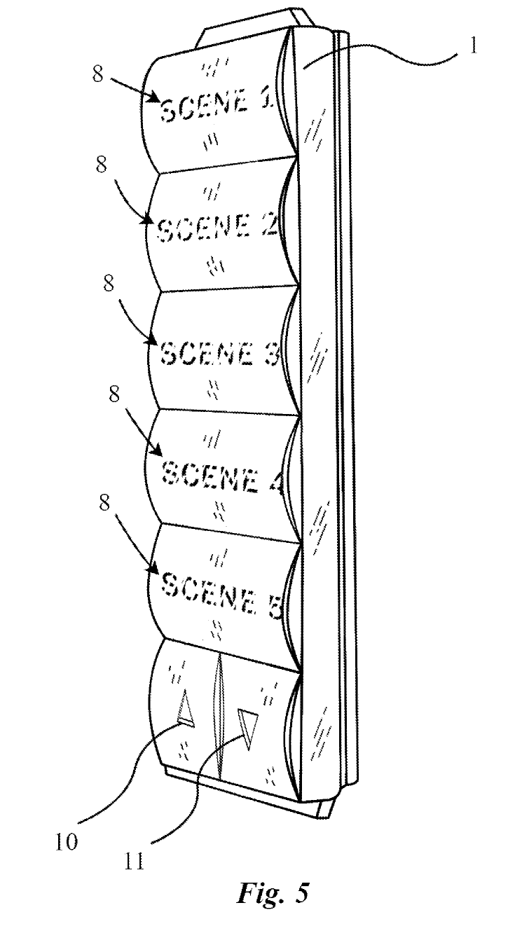

FIG. 5 further illustrates an embodiment where the transparent element's 1 touch surface is molded as a plurality of vertically adjacent semi-cylindrical buttons and the iconic symbols 8 depict words. The words can be descriptive of a function associated with an automation system.

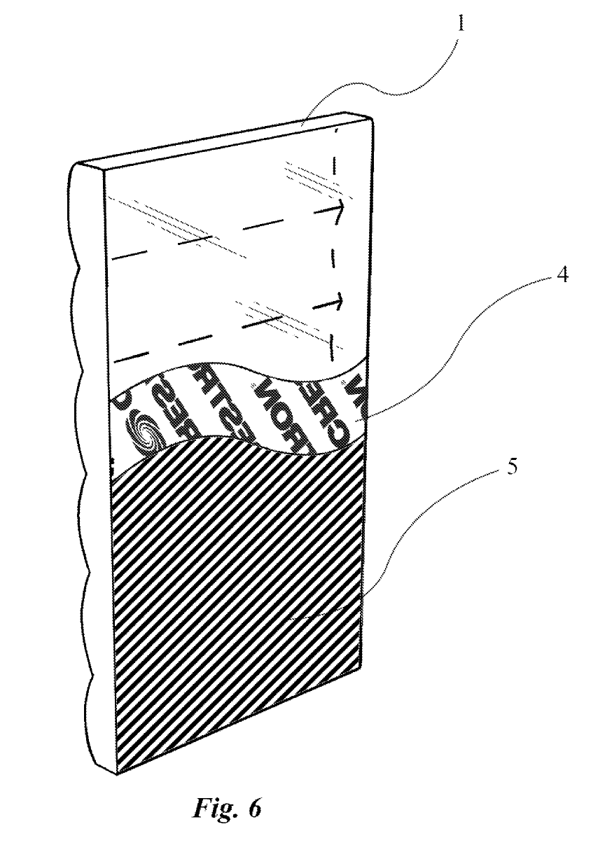

With reference to FIG. 6, the transparent element 1 has an ink layer 4 directly printed thereon. The ink layer may comprise a graphical depiction or text. The graphical depiction can be any combination of colors, patterns, textures, and gradients can be possible with the inks. The ink layer 4 can be printed using a translucent ultra-violet cured ink, printed using ink that dries through polymerization, or printed using a solvent based ink.

In one embodiment, the printing may employ a thermal ink jet process wherein the ink in the nozzles is selectively heated in a graphical pattern to cause droplets of the ink to be ejected in graphical pattern. In another embodiment, the printing apparatus employs an acoustic ink jet process, wherein droplets of the ink are caused to be ejected in graphical pattern by acoustic energy. Additionally, the printing process could further include pretreating the transparent element 1 with a primer or physical abrading to create a more ink receptive surface. If desired, an optional second diffusing layer 5 can be printed directly ontop of ink layer 4.

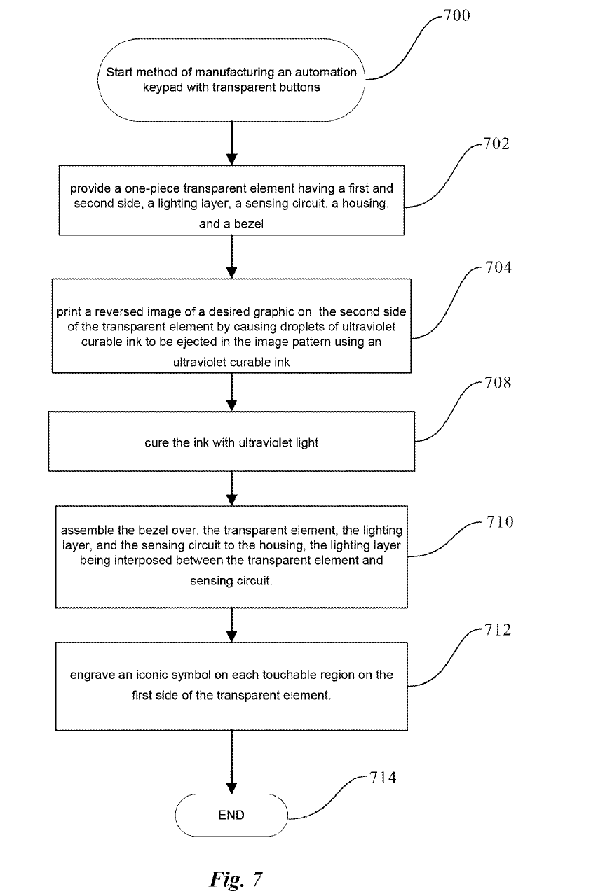

FIG. 7 shows a flowchart of a method of manufacturing an automation keypad with transparent buttons (step 700). The method comprises providing a one-piece transparent element having a first and second side, a lighting layer, a sensing circuit, a housing, and a bezel (step 702). Next, printing a reversed image of a desired graphic on the second side of the transparent element by causing droplets of ultraviolet curable ink to be ejected in the image pattern using an ultraviolet curable ink (step 704). Next, curing the ink with ultraviolet light (step 708). The next step entails assembling the bezel over, the transparent element, the lighting layer, and the sensing circuit to the housing, the lighting layer being interposed between the transparent element and sensing circuit (step 710). Next, engraving an iconic symbol on each touchable region on the first side of the transparent element (step 712).

Accordingly, by forming an image directly onto a transparent element there is no need for insert labels, although the methods disclosed herein can also be used with supplemental layers or other components.

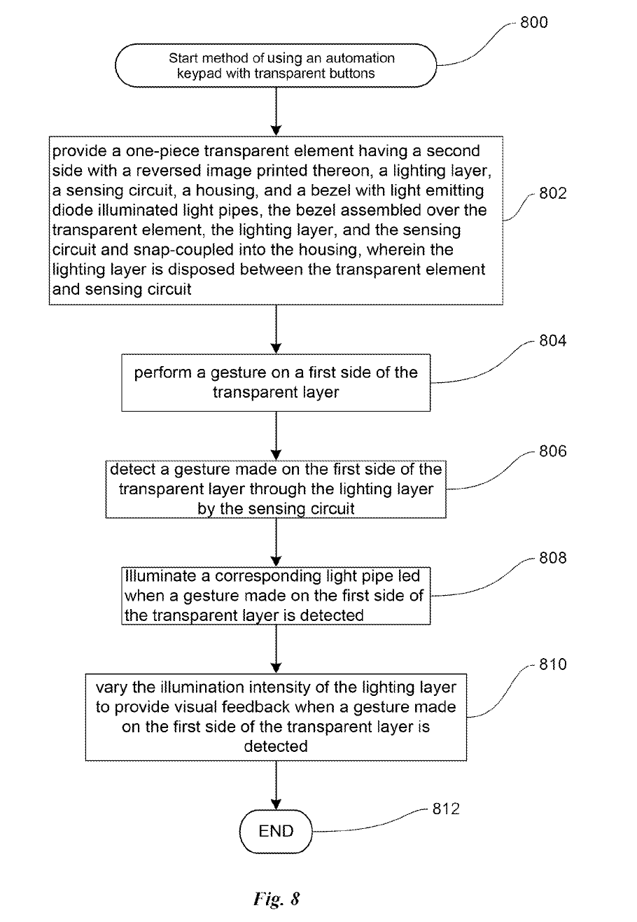

FIG. 8 shows a flowchart of a method of using an automation keypad with transparent buttons. The method comprises providing a one-piece transparent element having a second side with a reversed image printed thereon, a lighting layer, a sensing circuit, a housing, and a bezel with light emitting diode illuminated light pipes, the bezel assembled over the transparent element, the lighting layer, and the sensing circuit and snap-coupled into the housing, wherein the lighting layer is disposed between the transparent element and sensing circuit (step 802). Then, performing a gesture on a first side of the transparent layer (step 804). Then, detecting a gesture made on the first side of the transparent layer through the lighting layer by the sensing circuit (step 806). Then, illuminating a corresponding light pipe led when a gesture made on the first side of the transparent layer is detected (step 808). Then, varying the illumination intensity of the lighting layer to provide visual feedback when a gesture made on the first side of the transparent layer is detected (step 810).

In the foregoing specification, the invention has been described with reference to specific embodiments thereof. It will, however, be evident that various modifications and changes can be made thereto without departing from the broader spirit and scope of the invention as set forth in the appended claims. For example, the transparent element can be molded into any shape and be inked on using any known methods.

What is claimed is:

1. A keypad assembly comprising:
substantially transparent element having a first side and a second side, the second side presenting a flat region with an ink printed graphic thereon;
a lighting layer for illuminating the transparent element;
a sensing circuit for detecting touch and sliding gestures made on the first side of the transparent element;
a housing; and
a bezel for securing the transparent element, the lighting layer, and the sensing circuit to the housing, the lighting layer being interposed between the transparent element and sensing circuit, and the sensing circuit being configured detect gestures made on the first side of the transparent layer through the lighting layer.

2. The keypad assembly of claim 1, wherein the sensing circuit detects touch and sliding gestures using mutual capacitance.

3. The keypad assembly of claim 1, wherein the sensing circuit detects touch and sliding gestures using self-capacitance sensing.

4. The keypad assembly of claim 1, wherein the first side of the transparent element is molded to present a plurality of vertically adjacent semi-cylindrical buttons.

5. The keypad assembly of claim 1, wherein the first side of the transparent element provides a substantially flat touch surface.

6. The keypad assembly of claim 1, wherein the first side of the transparent element is engraved with one or more icons corresponding to automation functions.

7. The keypad assembly of claim 1, further comprising:
a motorized haptic module for generating vibration feedback in response to touch or sliding gestures made onto the first side of the transparent layer.

8. The keypad assembly of claim 1, wherein the transparent element is constructed of a material selected from the group consisting of: glass, acrylic, polymer, vinyl, polyester, polyethylene, polycarbonate, and styrene plastic.

9. The keypad assembly of claim 1, wherein the ink printed graphic is printed using translucent ultra-violet cured ink.

10. The keypad assembly of claim 1, wherein the ink printed graphic is printed using ink that dries through polymerization.

11. The keypad assembly of claim 1, wherein the ink printed graphic is printed using solvent based ink.

12. The keypad assembly of claim 1, further comprising:
a Bluetooth® micro-location beacon for indoor positioning, the beacon configured to conform to Bluetooth Low Energy standards.

13. The keypad assembly of claim 1, further comprising:
at least one infrared light emitting diode for transmitting information another devices.

14. The keypad assembly of claim 1, further comprising:
an optical image sensor, the optical sensor configured to capture visual data.

15. The keypad assembly of claim 14, wherein said optical image sensor is configured to capture a hand gesture made by a user.

16. The keypad assembly of claim 14, wherein said optical image sensor is configured to capture, a printed barcode, or a Quick Response (QR) Code.

17. The keypad assembly of claim 14, wherein the optical image sensor is configured to capture an ambient lighting level.

18. The keypad assembly of claim 14, wherein the optical image sensor is configured to capture biometric information comprising at least one of: a user's face, or a user's fingerprint.

19. The keypad assembly of claim 1, wherein the lighting layer further comprises a translucent light diffusing medium having one or more light emitting diodes uniformly illuminating the translucent light diffusing medium.

20. The keypad assembly of claim 19, wherein the one or more light emitting diodes varies illumination intensity to provide visual feedback according to an automation condition or function.

21. The keypad assembly of claim 1, further comprising:
a passive infrared sensor (PIR) for detecting motion in the proximity of the keypad assembly.

22. A method of manufacturing an automation keypad with transparent buttons, the method comprising the steps of:
providing a one-piece transparent element having a first and second side, a lighting layer, a sensing circuit, a housing, and a bezel;
printing a reversed image of a desired graphic on the second side of the transparent element by causing droplets of ultraviolet curable ink to be ejected in the image pattern using an ultraviolet curable ink;
curing the ink with ultraviolet light;
assembling the bezel over, the transparent element, the lighting layer, and the sensing circuit to the housing, the lighting layer being interposed between the transparent element and sensing circuit.

23. The method of claim 22, wherein the step of printing further comprises:
engraving an iconic symbol on each touchable region on the first side of the transparent element.

24. A method of using an automation keypad with transparent buttons, the method comprising the steps of:
providing a one-piece transparent element having a second side with a reversed image printed thereon, a lighting layer, a sensing circuit, a housing, and a bezel with light emitting diode illuminated light pipes, the bezel assembled over the transparent element, the lighting layer, and the sensing circuit and snap-coupled into the housing, wherein the lighting layer is disposed between the transparent element and sensing circuit;
performing a gesture on a first side of the transparent layer; and
detecting a gesture made on the first side of the transparent layer through the lighting layer by the sensing circuit.

25. The method of claim 24, further comprising the step of:
Illuminating a corresponding light pipe led when a gesture made on the first side of the transparent layer is detected.

26. The method of claim 24, further comprising the step of:
varying the illumination intensity of the lighting layer to provide visual feedback when a gesture made on the first side of the transparent layer is detected.

27. A keypad assembly comprising:
a substantially transparent element having a first side molded to present a plurality of vertically adjacent semi-cylindrical buttons and a second side presenting a flat region with an ink printed graphic thereon;
a lighting layer comprising a translucent light diffusing medium having one or more light emitting diodes uniformly illuminating the translucent light and the transparent element;
a sensing circuit for detecting touch and sliding gestures made on the first side of the transparent layer;
a housing; and
a bezel for securing the transparent element, the lighting layer, and the sensing circuit to the housing, the lighting layer being interposed between the transparent element and sensing circuit, and the sensing circuit being configured detect gestures made on the first side of the transparent layer through the lighting layer.
